(19) United States
(12) Patent Application Publication
(10) Pub. No.: US 2025/0210453 A1
(43) Pub. Date: Jun. 26, 2025

(54) MICRO VAPOR CHAMBER LIDS

(71) Applicant: Advanced Micro Devices, Inc., Santa Clara, CA (US)

(72) Inventors: Joshua Taylor Knight, Austin, TX (US); William R. Alverson, Austin, TX (US); Amitabh Mehra, Ft. Collins, CO (US); Grant Evan Ley, Ft. Collins, CO (US); Anil Harwani, Austin, TX (US); Jerry A. Ahrens, Austin, TX (US)

(73) Assignee: Advanced Micro Devices, Inc., Santa Clara, CA (US)

(21) Appl. No.: 18/393,869

(22) Filed: Dec. 22, 2023

(51) Int. Cl. H01L 23/427

(52) U.S. Cl. CPC H01L 23/427

(57) ABSTRACT

A thermal management system for an integrated circuit can include plural micro vapor chambers each configured to operate within their local environment. An exemplary system includes a semiconductor die, a first micro vapor chamber coupled with a first region of the semiconductor die, and a second micro vapor chamber coupled with a second region of the semiconductor die.

### BACKGROUND

Approaches to thermal management are ubiquitous within the microprocessor industry where rapid performance growth has been accompanied by an increase in transistor density and an attendant increase in heat generation within electronic packages. Absent effective solutions, excessive heat retention and large thermal gradients can adversely impact the performance and reliability of semiconductor devices.

### BRIEF DESCRIPTION OF THE DRAWINGS

The accompanying drawings illustrate a number of example implementations and are a part of the specification. Together with the following description, these drawings demonstrate and explain various principles of the present disclosure.

FIG. 1 is a schematic drawing illustrating the structure and operation of a micro vapor chamber according to various implementations.

FIG. 2 shows an exemplary device architecture having regions configured to be independently thermally managed by a plurality of co-integrated micro vapor chambers according to some implementations.

FIG. 3 is a cross-sectional view showing multiple micro vapor chambers co-integrated with a CPU processor according to some implementations.

FIG. 4 is an example core chiplet floor plan with a dedicated micro vapor chamber for each core according to various implementations.

FIG. 5 is an example core chiplet floor plan having a unified micro vapor chamber for each core group according to various implementations.

FIG. 6 is a top down plan view of a multi chiplet processor having a micro vapor chamber for each chiplet according to certain implementations.

FIG. 7 is a flow chart illustrating an example method of manufacturing a CPU processor with co-integrated micro vapor chambers according to certain implementations.

Throughout the drawings, identical reference characters and descriptions indicate similar, but not necessarily identical, elements. While the example implementations described herein are susceptible to various modifications and alternative forms, specific implementations have been shown by way of example in the drawings and will be described in detail herein. However, the example implementations described herein are not intended to be limited to the particular forms disclosed. Rather, the present disclosure covers all modifications, equivalents, and alternatives falling within the scope of the appended claims.

### DETAILED DESCRIPTION OF EXAMPLE IMPLEMENTATIONS

Vapor chambers are passive, two-phase devices configured to dissipate heat through vapor transport within a hermetically sealed cavity. A vapor chamber can be located adjacent to a portion of a device to be cooled, such as a hotspot. During operation, a working fluid is driven to a heated region of the chamber through capillary action within a porous wick structure where it evaporates, spreads throughout the cavity in vapor form, and condenses on the opposing cold face of the chamber, i.e., a condenser. The condensed liquid is then recirculated to the heated area, allowing the cycle to be repeated and effectuate cooling of the device.

An advantage of a vapor chamber is that it can be used as a heat flux transformer, cooling a high heat flux from an electronic chip or laser diode, for example, and transforming it to a lower heat flux that can be removed by natural or forced convection. The vapor acts as a heat spreader that can transform a relatively concentrated heat flux at the hotspot to a substantially uniform heat flux at the condenser. Thus, a vapor chamber can be used for high heat flux applications, or when two-dimensional heat spreading is beneficial.

The porous wick structure, which is located on the evaporator side of the vapor chamber, is configured to supply an effective amount of fluid to the heated region while maintaining a low thermal resistance pathway for heat transfer. Example wicking materials can include bi-porous and hierarchical porous structures that enable fluid, e.g., liquid, transport while possessing low thermal resistance. Further example wick structures can include sintered, grooved, and mesh/bundled fiber wicks, such as a copper sintered structure.

As will be appreciated, one or more of the power handling capacity of a vapor chamber, the ability to transport the working fluid against gravity, the ease with which the working fluid is vaporized, and the ability to handle higher heat fluxes can be tuned by varying the wick geometry, including its shape, thickness, and porosity.

At the condenser side of the vapor chamber, condensation ideally occurs without the formation of a high thermal resistance, bulk fluid layer. Additionally, the condenser side can be configured to return the fluid to the evaporator side wick. In a capillary-driven vapor chamber, for example, the condenser side can be lined with a porous wick that is adapted to deliver liquid back to the evaporator side wick while inhibiting the formation of a bulk liquid layer. Alternatively, a wickless condenser can be used if the vapor chamber is oriented to allow gravity-driven fluid flow back to the evaporator. In accordance with further implementations, a rheologically-structured surface, such as a superhydrophobic microstructured surface, can be configured to provide liquid return via droplet jumping.

The evacuation of non-condensable gases from the vapor chamber can prevent the formation of a diffusion barrier that would inhibit vapor transport between the evaporator and condenser. Adequate evacuation of the vapor chamber and the maintenance of a hermetic seal throughout repeated operation can be important in both design and manufacture. In various implementations, the evacuation of non-condensable gases creates a saturated, two-phase system, where the internal pressure is directly correlated with the operating temperature. An operating temperature can therefore be constrained by a critical burst pressure, which can be particularly relevant for vapor chambers formed from brittle materials such as silicon.

Comparative vapor chamber systems are designed to include a single vapor chamber for an entire piece of silicon, i.e., chip, and are broadly configured for whole chip level operation. Accordingly, such macro vapor chambers typically lack suitable efficiency over a broad operational range and are therefore unsatisfactory solutions for both single threaded (1T) hotspots and multi-threaded (NT) full power scenarios across full and extended operation paradigms.

Notwithstanding recent developments, it would be advantageous to provide a custom thermal management solution that includes plural vapor chambers each configured for efficient operation based on local operating conditions, including maximum and average temperatures, temperature gradients, and an amount of total power requiring thermal dissipation within a given region of a device.

Disclosed is a multi-micro vapor chamber thermal management system that is configured to effectuate cooling of a semiconductor device or chip. Each vapor chamber can be characterized by a relatively narrow but efficient range of operation where parameters such as the fluid evaporation temperature, fluid quantity within the chamber, wick dry out temperature, etc., are tuned for a given power or temperature dissipation band. That is, attributes of the micro chambers including, for example, the dimensions, volume, and internal pressure of the chamber itself, the composition and structure of the wicking material, the volume and composition of the fluid, etc. can be selected independently and in any suitable combination for each micro chamber. For instance, the fluid within any given micro vapor chamber can be a single component (e.g., water or alcohol) or a fluid mixture (e.g., water and alcohol combined at any suitable ratio) and the fluid composition amongst different micro vapor chambers can be equivalent or different.

Plural micro vapor chambers can be incorporated into an integrated heat spreader or lid and affixed to a printed circuit board, for example. The vapor chambers can be coupled with a die, for example, and configured to absorb and dissipate heat generated by the die. The plural micro vapor chambers can be individually tuned and co-integrated for the specific cooling requirements that are needed for each respective microprocessor block or component being cooled, including per core cooling. By using multiple vapor chambers, the quantity of silicon each chamber is configured to cool can be greatly reduced and each chamber can therefore be custom tuned to the operating band of the associated device region being cooled. For instance, within each zone to be cooled, a dedicated micro vapor chamber can be configured to initiate evaporation and hence initiate cooling at a designated temperature while avoiding evaporation of the entire liquid volume (or localized dry out within an overheated sub-region), which can result in thermal runaway and overheating. Such an approach enables more efficient cooling, particularly with operationally diverse devices such as multi-chip modules, where different regions of the device can be implemented with different process technologies, core architectures, power interfaces, and the like. In some implementations, a micro vapor chamber can be configured for cooling applications where the power density within the targeted area ranges from approximately 10 W/cm² to approximately 500 W/cm².

An integrated heat spreader or lid can include two or more micro vapor chambers, where each micro vapor chamber can be located directly over a corresponding chip or processor (or region thereof) and tuned for the heat output of that individual component. As will be appreciated, the number of micro vapor chambers in an exemplary thermal management system is not particularly limited, and can range from 2 to 10 or more, e.g., 2, 4, 6, 8, or 10, including ranges between any of the foregoing values.

The relatively small areal dimensions of the presently-disclosed micro vapor chambers can obviate the need for structural support elements, such as pillars that extend across the chamber volume. The elimination of such structural elements can improve the operation and efficiency of the micro vapor chambers relative to larger vapor chambers insomuch as the ‘support pillars’ in the larger chambers can impede the evaporative flow by changing the shape of the chamber as well as providing a non-wick pooling or condensation point. In accordance with certain implementations, the areal dimensions (i.e., length and width) of a micro vapor chamber can independently range from approximately 0.1 mm to approximately 10 mm, including ranges between any of the foregoing values, although lesser and greater micro vapor chamber dimensions are contemplated. For instance, a micro vapor chamber can have a lateral dimension (i.e., a maximum lateral dimension) of less than approximately 10 mm.

According to some implementations, in addition to aligning the plural micro vapor chambers with respective regions of a silicon chip or die, the lid can be mechanically and thermally aligned with a suitable heat sink, including associated cooling points or heat pipe locations with respective cooling needs, to provide an effective and efficient cooling solution that addresses the global needs of the system.

An exemplary system can include a semiconductor die, a first micro vapor chamber coupled with a first region of the semiconductor die, and a second micro vapor chamber coupled with a second region of the semiconductor die. The semiconductor die can include a silicon chip, for example, and can include a central processing unit (CPU) core. For instance, the first region of the semiconductor die can include a first CPU core and the second region of the semiconductor die can include a second CPU core. Additionally or alternatively, a semiconductor die may include a graphics processing unit (GPU), a configurable processing unit, an integrated circuit, and the like.

In various instantiations, the first and second micro vapor chambers can be disposed within an integrated heat spreader overlying the semiconductor die such that the first and second micro vapor chambers each directly overlie a respective region of the semiconductor die and are independently configured to remove heat from respective regions of the die.

Suitable working fluids include water and alcohol, as well as mixtures thereof. In some implementations, the first and second micro vapor chambers can each have a maximum lateral dimension of less than approximately 10 mm.

A further exemplary system can include a semiconductor die and an integrated heat spreader overlying the semiconductor die, where the integrated heat spreader includes a first micro vapor chamber adapted to cool a first region of the semiconductor die, and a second micro vapor chamber adapted to cool a second region of the semiconductor die.

A method of cooling a semiconductor die can include contacting a first micro vapor chamber with a first region of the semiconductor die and contacting a second micro vapor chamber with a second region of the semiconductor die. In certain methods, the first and second micro vapor chambers can be formed within an integrated heat spreader.

An integrated heat spreader or lid including plural micro vapor chambers can be configured to cool different regions a semiconductor die. In particular implementations, a power density within at least one of the first and second regions of the semiconductor die during operation thereof can range from approximately 10 W/cm² to approximately 500 W/cm². The heat dissipation rates amongst the regions being cooled can be equal or unequal.

A thermal management system for a semiconductor device includes a lid having multiple micro vapor chambers each configured for efficient operation within a localized band of operational parameters, including targeted power or temperature dissipation bands. The thermal management system can include an array of micro vapor chambers located within the integrated heat spreader of a central processing unit, for example. Each of the plurality of micro vapor chambers can be configured to cool a corresponding area of a chip, including various functional regions, and thereby provide an efficient cooling function across a broad operating range for the underlying chip or device.

Features from any of the implementations described herein can be used in combination with one another in accordance with the general principles described herein. These and other implementations, features, and advantages will be more fully understood upon reading the following detailed description in conjunction with the accompanying drawings and claims.

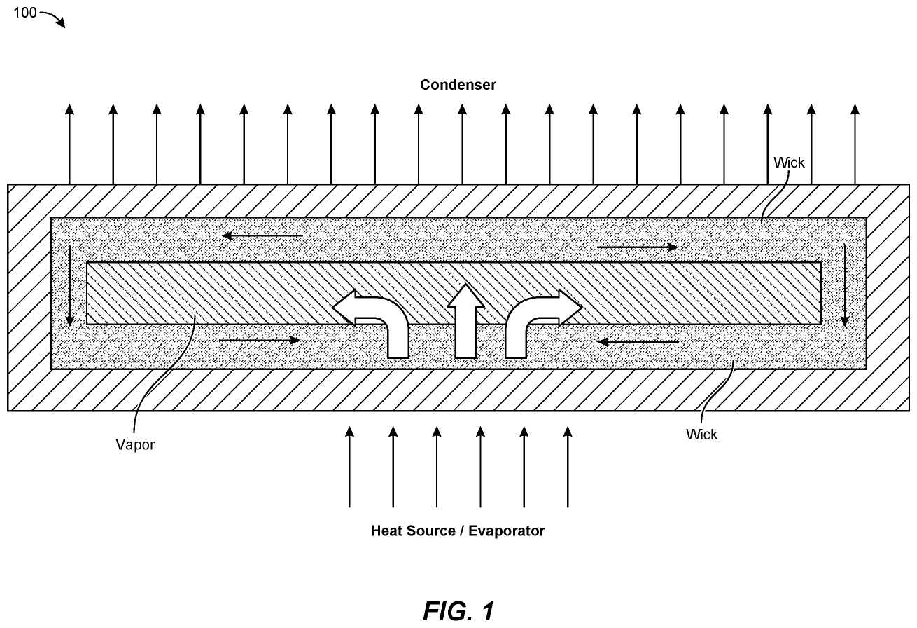

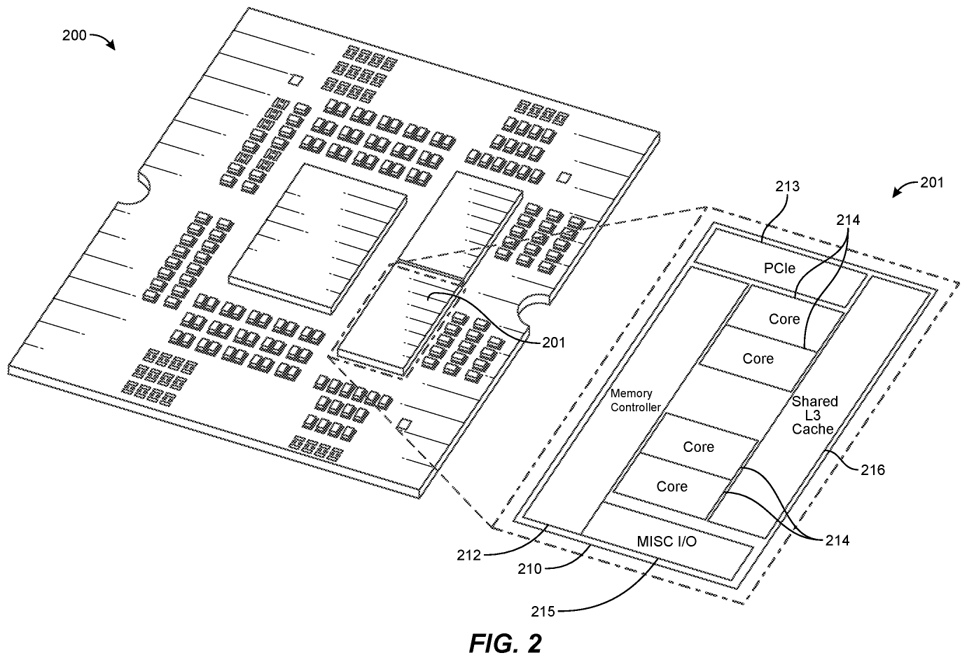

The present disclosure is generally directed to micro vapor chamber lids, and more specifically to locally-configured micro vapor chambers for improved thermal management in electronic devices. The structure and principle of operation of an example micro vapor chamber are illustrated schematically in FIG. 1. A simplified device architecture including co-integrated and independently configured micro vapor chambers is shown in FIG. 2.

Turning to FIG. 1, shown schematically is the operating principle for a phase change heat transfer device. During operation, heat from a heat source is absorbed by the evaporator, which causes the working fluid to vaporize and travel to the condenser where it condenses into a liquid, releasing the absorbed heat. The working fluid is returned to the evaporator via a wick structure allowing the phase change heat transfer cycle to be repeated.

According to certain implementations, the micro vapor chamber 100 illustrated in FIG. 1 can be combined with further such micro vapor chambers to form an integrated heat spreader (or lid) adapted to effectuate cooling of a semiconductor device, such as a silicon chip, where each of the plurality of micro vapor chambers within the integrated heat spreader directly overlies and is thermally coupled with a respective portion of the device.

FIG. 2 is a perspective view of a desktop processor 200 showing CPU cores 201 and, in the inset view, an exemplary core floor plan 210. Within the CPU core 201, shown schematically are various active regions, including a memory controller 212, serial interface 213, core processors 214, I/O bus 215, and shared cache 216.

In exemplary implementations, a cooling solution for a desktop processor 200 can include an overlying micro vapor chamber lid (not shown) having a plurality of co-integrated micro vapor chambers each directly overlying and configured optimally to cool a respective active area and meet that active area's unique cooling needs/power dissipation bands 212-216.

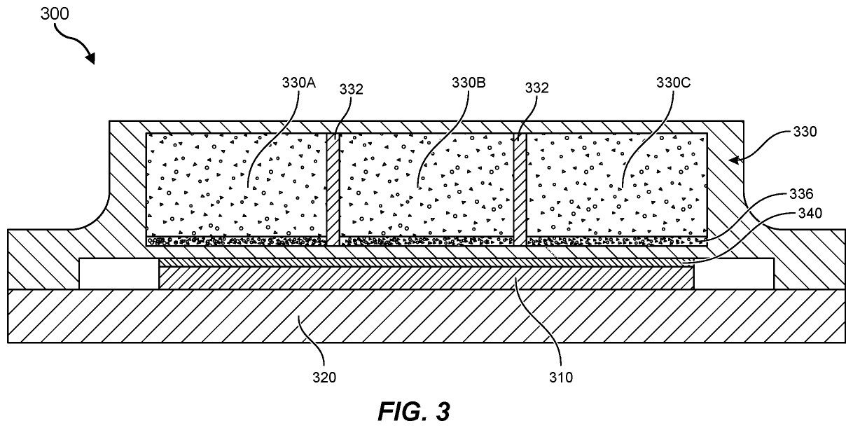

FIG. 3 is a cross-sectional view of an example CPU processor co-integrated with multiple micro vapor chambers. In the example CPU processor 300, a layer of active silicon 310 including a semiconductor chip or a combination of chiplets (not separately shown) overlies a substrate or printed circuit board (PCB) 320. An integrated heat spreader 330 overlies the layer of active silicon 310. A bonding metal layer 340 can be used to attach the layer of active silicon 310 with the integrated heat spreader 330.

The illustrated integrated heat spreader 330 includes a plurality of microchambers 330A, 330B, 330C separated by pillars 332. During use, a working fluid 336 in both vapor and liquid states is located within each of the microchambers 330A, 330B, 330C.

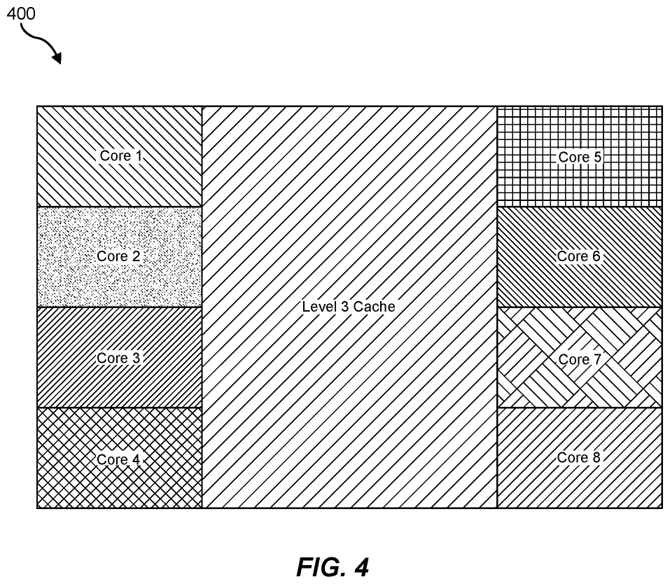

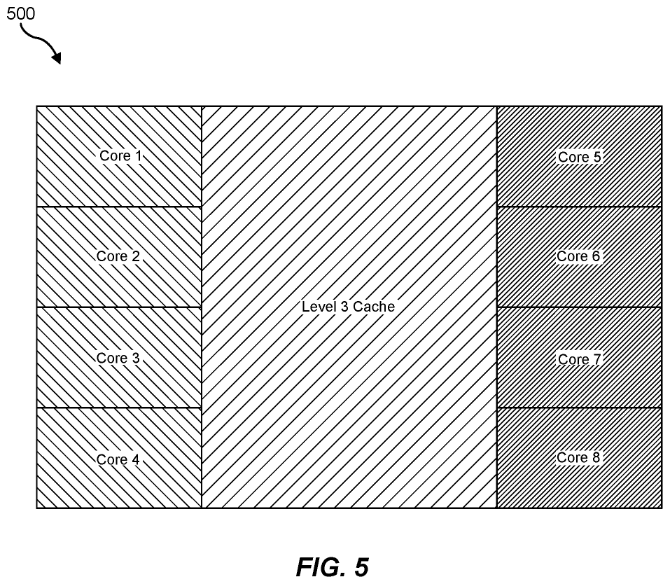

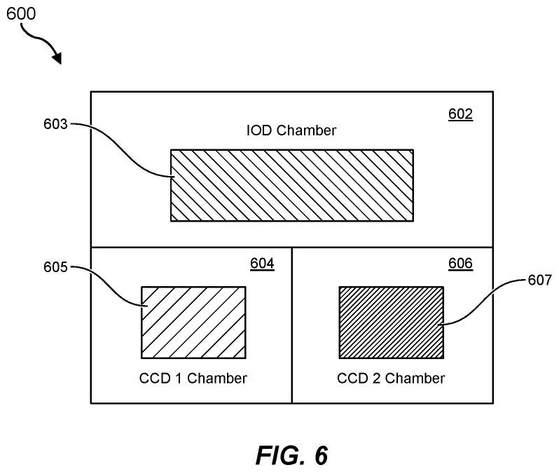

Referring to FIGS. 4 and 5, shown are example chiplet floor plans and corresponding micro vapor chamber configurations. Floor plan 400 of FIG. 4 includes a pair of core clusters having four cores each separated by a block of level 3 (L3) cache. Each core (1-8) and the L3 cache include a dedicated micro vapor chamber. In floor plan 500 of FIG. 5, a unified micro vapor chamber overlies each core cluster (cores 1, 3, 5, 7 and cores 2, 4, 6, 8), and a further micro vapor chamber overlies the L3 cache. Referring to FIG. 6, a processor 600 can include plural chiplets 602, 604, 606 each having an associated micro vapor chamber 603, 605, 607.

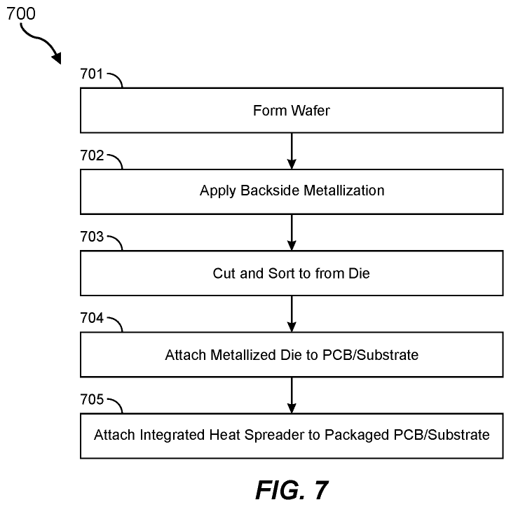

A flowchart describing a method of forming a semiconductor device including one or more integrated micro vapor chambers is shown in FIG. 7. An example method 700 can include forming devices on a semiconductor wafer (701), forming a bonding metal layer over a backside of the wafer (702), dicing the wafer to form plural die (703), attaching the metallized die to a substrate or printed circuit board (PCB) (704), and attaching an integrated heat spreader to the packaged PCB/substrate (705).

While the foregoing disclosure sets forth various implementations using specific block diagrams, flowcharts, and examples, each block diagram component, flowchart step, operation, and/or component described and/or illustrated herein can be implemented, individually and/or collectively, using a wide range of hardware, software, or firmware (or any combination thereof) configurations. In addition, any disclosure of components contained within other components should be considered example in nature since many other architectures can be implemented to achieve the same functionality.

The process parameters and sequence of steps described and/or illustrated herein are given by way of example only and can be varied as desired. For example, while the steps illustrated and/or described herein can be shown or discussed in a particular order, these steps do not necessarily need to be performed in the order illustrated or discussed. The various example methods described and/or illustrated herein can also omit one or more of the steps described or illustrated herein or include additional steps in addition to those disclosed.

The preceding description has been provided to enable others skilled in the art to best utilize various aspects of the example implementations disclosed herein. This example description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

The term “approximately” in reference to a particular numeric value or range of values can, in certain implementations, mean and include the stated value as well as all values within 10% of the stated value. Thus, by way of example, reference to the numeric value “50” as “approximately 50” can, in certain implementations, include values equal to 50±5, i.e., values within the range 45 to 55.

The term “substantially” in reference to a given parameter, property, or condition can mean and include to a degree that one of ordinary skill in the art would understand that the given parameter, property, or condition is met with a small degree of variance, such as within acceptable manufacturing tolerances. By way of example, depending on the particular parameter, property, or condition that is substantially met, the parameter, property, or condition can be at least approximately 90% met, at least approximately 95% met, or even at least approximately 99% met.

It will be understood that when an element such as a layer or a region is referred to as being formed on, deposited on, or disposed “on” or “over” another element, it can be located directly on at least a portion of the other element, or one or more intervening elements can also be present. In contrast, when an element is referred to as being “directly on” or “directly over” another element, it can be located on at least a portion of the other element, with no intervening elements present.

While various features, elements or steps of particular implementations can be disclosed using the transitional term “comprising,” it is to be understood that alternative implementations, including those that can be described using the transitional phrases “consisting of” or “consisting essentially of,” are implied. Thus, for example, implied alternative implementations to a semiconductor substrate that comprises or includes silicon include implementations where a semiconductor substrate consists essentially of silicon and implementations where a semiconductor substrate consists of silicon.

What is claimed is:

1. A system comprising:
a semiconductor die;
a first micro vapor chamber coupled with a first region of the semiconductor die; and
a second micro vapor chamber coupled with a second region of the semiconductor die.

2. The system of claim 1, wherein the semiconductor die comprises a silicon chip.

3. The system of claim 1, wherein the semiconductor die comprises a processing element selected from the group consisting of a central processing unit (CPU), a graphics processing unit (GPU), a configurable processing unit, and an integrated circuit.

4. The system of claim 1, wherein the first region of the semiconductor die comprises a first central processing unit (CPU) core and the second region of the semiconductor die comprises a second central processing unit (CPU) core.

5. The system of claim 1, wherein the first and second micro vapor chambers are disposed within an integrated heat spreader overlying the semiconductor die.

6. The system of claim 1, wherein the first and second micro vapor chambers each directly overlie a respective region of the semiconductor die.

7. The system of claim 1, wherein the first and second micro vapor chambers are independently configured to remove heat from respective regions of the semiconductor die.

8. The system of claim 1, wherein the first and second micro vapor chambers each comprise a fluid independently selected from the group consisting of water and an alcohol.

9. The system of claim 1, wherein the first and second micro vapor chambers each have a maximum lateral dimension of less than approximately 10 mm.

10. The system of claim 1, further comprising a third micro vapor chamber coupled with a third region of the semiconductor die.

11. A system comprising:
a semiconductor die; and
a integrated heat spreader overlying the semiconductor die, wherein the integrated heat spreader comprises:
a first micro vapor chamber adapted to cool a first region of the semiconductor die; and
a second micro vapor chamber adapted to cool a second region of the semiconductor die.

12. The system of claim 11, wherein the first region of the semiconductor die comprises a first central processing unit (CPU) core and the second region of the semiconductor die comprises a second central processing unit (CPU) core.

13. The system of claim 11, wherein the first and second micro vapor chambers each directly overlie a respective region of the semiconductor die.

14. The system of claim 11, wherein the first and second micro vapor chambers each comprise a fluid independently selected from the group consisting of water and an alcohol.

15. The system of claim 11, wherein the first and second micro vapor chambers each have a maximum lateral dimension of less than approximately 10 mm.

16. A method comprising:
contacting a first micro vapor chamber with a first region of a semiconductor die; and
contacting a second micro vapor chamber with a second region of the semiconductor die.

17. The method of claim 16, comprising forming the first and second micro vapor chambers within an integrated heat spreader.

18. The method of claim 16, wherein a power density within at least one of the first and second regions of the semiconductor die ranges from approximately 10 W/cm² to approximately 500 W/cm².

19. The method of claim 16, wherein the first and second micro vapor chambers are independently configured to remove heat from respective regions of the semiconductor die.

20. The method of claim 16, wherein a heat dissipation rate from the first region of the semiconductor die is less than a heat dissipation rate from the second region of the semiconductor die.
